(19) United States
(12) Patent Application Publication
(10) Pub. No.: US 2025/0231553 A1
(43) Pub. Date: Jul. 17, 2025

(54) INFORMATION PROCESSING APPARATUS, SEMICONDUCTOR MANUFACTURING APPARATUS, AND INFORMATION PROCESSING METHOD

(71) Applicant: Tokyo Electron Limited, Tokyo (JP)

(72) Inventors: Yusuke TSUCHIYA, Hokkaido (JP); Nobutoshi TERASAWA, Hokkaido (JP)

(21) Appl. No.: 19/012,374

(22) Filed: Jan. 7, 2025

(30) Foreign Application Priority Data
Jan. 15, 2024 (JP) 2024-003814

(51) Int. Cl. G05B 19/418

(52) U.S. Cl. CPC G05B 19/41875; G05B 2219/45031

(57) ABSTRACT

An information processing apparatus includes a grouping information generation unit that acquires a setting value for each processing step executed by a semiconductor manufacturing apparatus according to the setting value, and generates information for grouping processing steps executed according to the same setting value; a data extraction unit that extracts at least one second processing step that has a setting value identical to a setting value of a first processing step and that is executed before the first processing step when the setting value of the first processing step specified from a time when an abnormality occurred is included in the information for grouping; an analysis target section setting unit that sets the first processing step and the second processing step as an analysis target section; and a display control unit that displays a graph indicating an analysis result of the analysis target section.

### CROSS-REFERENCE TO RELATED APPLICATIONS

This application is based on and claims priority from Japanese Patent Application No. 2024-003814 filed on Jan. 15, 2024 with the Japan Patent Office, the disclosure of which is incorporated herein in its entirety by reference.

### TECHNICAL FIELD

The present disclosure relates to an information processing apparatus, a semiconductor manufacturing apparatus, and an information processing method.

### BACKGROUND

Techniques for detecting an abnormality of a semiconductor manufacturing apparatus, using a chart that displays time series information measured in the semiconductor manufacturing apparatus, such as a statistical process control (SPC) chart, a correlation chart, or a merchandising (MD) chart, have been known in the related art (e.g., Japanese Patent Application Laid-Open No. 2021-068831).

### SUMMARY

One aspect of the present disclosure provides an information processing apparatus. The information processing apparatus includes a grouping information generation unit that acquires a setting value for each processing step executed by a semiconductor manufacturing apparatus according to the setting value, and generates information for grouping processing steps executed according to the same setting value; a data extraction unit that extracts at least one second processing step that has a setting value identical to a setting value of a first processing step and that is executed before the first processing step when the setting value of the first processing step specified from a time when an abnormality occurred is included in the information for grouping; an analysis target section setting unit that sets the first processing step and the second processing step as an analysis target section; and a display control unit that displays a graph indicating an analysis result of the analysis target section.

The foregoing summary is illustrative only and is not intended to be in any way limiting. In addition to the illustrative aspects, embodiments, and features described above, further aspects, embodiments, and features will become apparent by reference to the drawings and the following detailed description.

### BRIEF DESCRIPTION OF THE DRAWINGS

FIG. 1 is a configuration diagram of a semiconductor manufacturing system according to an embodiment of the present disclosure.

FIG. 2 is a hardware configuration diagram of a computer.

FIG. 3 is a functional block diagram of an autonomous controller according to the present embodiment.

FIG. 4 is a functional block diagram of an event method trend graph generation unit according to the present embodiment.

FIG. 5 is an explanatory diagram of information defining the state of a semiconductor manufacturing apparatus.

FIG. 6 is an explanatory diagram of information defining a statistical processing method.

FIG. 7 is a functional block diagram of a stepwise trend graph generation unit according to the present embodiment.

FIG. 8 is a flowchart of a process for generating a step catalog according to the present embodiment.

FIG. 9 is a flowchart of a process for displaying a trend graph according to the present embodiment.

FIG. 10 describes the Run of a semiconductor manufacturing apparatus where an alarm has occurred as Alarm Run.

FIG. 11 is a diagram explaining a generated trend graph.

FIG. 12 is a diagram explaining a scoring method for calculating a score of a trend graph.

### DETAILED DESCRIPTION

In the following detailed description, reference is made to the accompanying drawings, which form a part thereof. The illustrative embodiments described in the detailed description, drawings, and claims are not meant to be limiting. Other embodiments may be utilized, and other changes may be made without departing from the spirit or scope of the subject matter presented here.

Hereinafter, embodiments of the present disclosure will be described with reference to the drawings.

### <System Configuration>

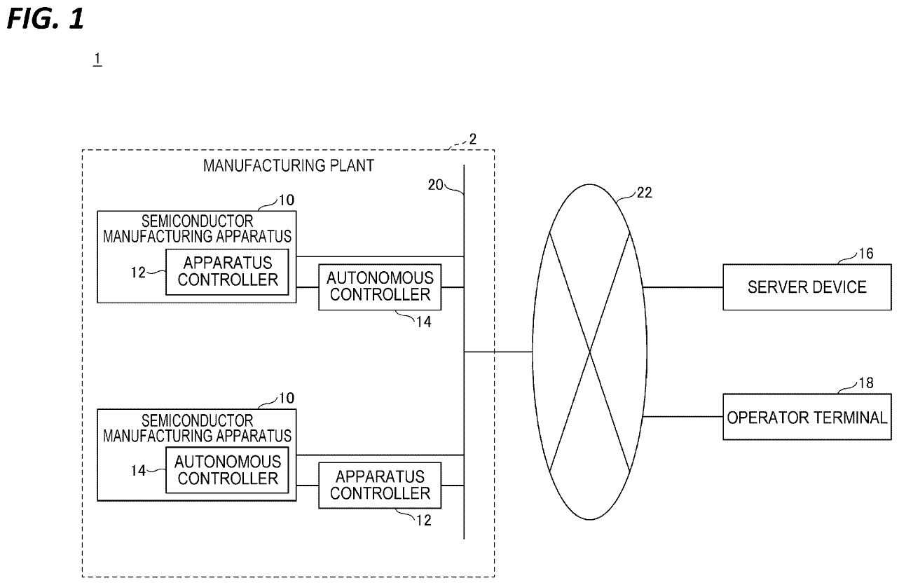

FIG. 1 is a configuration diagram of a semiconductor manufacturing system 1 according to an embodiment of the present disclosure. The semiconductor manufacturing system 1 illustrated in FIG. 1 includes a semiconductor manufacturing apparatus 10, an apparatus controller 12, an autonomous controller 14, a server device 16, and an operator terminal 18.

The semiconductor manufacturing apparatus 10, the apparatus controller 12, and the autonomous controller 14 are installed in a manufacturing plant 2. The server device 16 and the operator terminal 18 may be installed in the manufacturing plant 2 or may be installed outside the manufacturing plant 2. The operator terminal 18 is an information processing terminal such as a personal computer (PC) or a smartphone operated by an operator such as an apparatus manager or an analysis manager of the semiconductor manufacturing apparatus 10 installed in the manufacturing plant 2.

The semiconductor manufacturing apparatus 10, the apparatus controller 12, the autonomous controller 14, the server device 16, and the operator terminal 18 are communicatively connected to networks 20 and 22 such as the Internet or local area network (LAN).

The semiconductor manufacturing apparatus 10 is an apparatus that performs a processing, such as a film forming processing, an etching processing, or an ashing processing, and processes, for example, a semiconductor wafer (hereinafter, simply referred to as a wafer). The semiconductor manufacturing apparatus 10 is, for example, a substrate processing apparatus, a heat treatment apparatus, or a film forming apparatus.

The semiconductor manufacturing apparatus 10 receives, for example, control instructions (setting values) according to a recipe, from the apparatus controller 12, and executes a process. The semiconductor manufacturing apparatus 10 is equipped with a plurality of sensors such as a temperature sensor that measures a temperature and a pressure sensor that measures a pressure.

The apparatus controller 12 has the function of a man-machine interface that receives instructions for the semiconductor manufacturing apparatus 10 from an operator and provides information regarding the semiconductor manufacturing apparatus 10 to the operator. The apparatus controller 12 receives sensor data output from the plurality of sensors installed in the semiconductor manufacturing apparatus 10. The apparatus controller 12 may perform optimization of the setting value of the semiconductor manufacturing apparatus 10, abnormality detection, or abnormality prediction.

The apparatus controller 12 illustrated in FIG. 1 is installed in each semiconductor manufacturing apparatus 10, but may be installed for a plurality of semiconductor manufacturing apparatuses 10. The apparatus controller 12 may be installed within a housing of the semiconductor manufacturing apparatus 10 or may be installed outside the housing.

The autonomous controller 14 is a controller for autonomously controlling the semiconductor manufacturing apparatus 10. The autonomous controller 14 receives sensor data output from the plurality of sensors installed in the semiconductor manufacturing apparatus 10. The autonomous controller 14 performs optimization of the setting value of the semiconductor manufacturing apparatus 10, abnormality detection, or abnormality prediction. The autonomous controller 14 illustrated in FIG. 1 is installed in each semiconductor manufacturing apparatus 10, but may be installed for a plurality of semiconductor manufacturing apparatuses 10. The autonomous controller 14 may be installed within the housing of the semiconductor manufacturing apparatus 10, or may be installed outside the housing.

The server device 16 may receive sensor data output from the plurality of sensors installed in the semiconductor manufacturing apparatus 10, and may store the sensor data as a process log for each execution of a process (hereinafter, referred to as Run).

The server device 16 may store information regarding the plurality of semiconductor manufacturing apparatuses 10 of one or more manufacturing plants 2 (setting values of processes executed in the semiconductor manufacturing apparatuses 10, sensor data used when the processes are executed according to the setting values, and result data) as a process log for each Run.

The apparatus controller 12, the autonomous controller 14, and the server device 16 may display the information regarding the semiconductor manufacturing apparatuses 10 on the operator terminal 18, or may notify an operator of the operator terminal 18 using e-mail. The apparatus controller 12, the autonomous controller 14, the server device 16, and the operator terminal 18 illustrated in FIG. 1 are examples of an information processing apparatus according to the present embodiment.

The semiconductor manufacturing system 1 illustrated in FIG. 1 is provided by way of an example, and various examples of system configurations may be provided depending on usage or purposes. The classification of apparatuses such as the apparatus controller 12, the autonomous controller 14, and the server device 16 illustrated in FIG. 1 is provided by way of an example. For example, the semiconductor manufacturing system 1 may have various configurations, such as a configuration in which at least two of the apparatus controller 12, the autonomous controller 14, and the server device 16 are integrated, or a configuration in which they are further divided. In addition, the apparatus controller 12 and the autonomous controller 14 may handle the plurality of semiconductor manufacturing apparatuses 10 in an integrated manner.

### <Hardware Configuration>

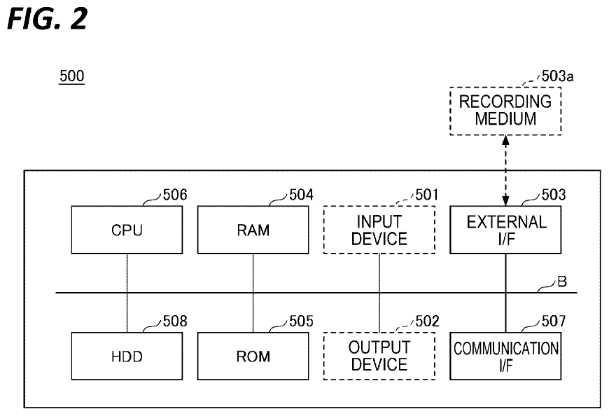

The apparatus controller 12, the autonomous controller 14, the server device 16, and the operator terminal 18 illustrated in FIG. 1 may be implemented by a computer having a hardware configuration illustrated in FIG. 2, for example. FIG. 2 is a hardware configuration diagram of a computer 500.

The computer 500 of FIG. 2 includes an input device 501, an output device 502, an external I/F (interface) 503, a random access memory (RAM) 504, a read only memory (ROM) 505, a central processing unit (CPU) 506, a communication I/F 507, and a hard disk drive (HDD) 508, each of which is connected by a bus B. The input device 501 and the output device 502 may be connected and used as needed.

The input device 501 is a keyboard, a mouse, or a touch panel and is used to input each operational signal by an operator. The output device 502 is a display and displays a result of processing by the computer 500. The communication I/F 507 is an interface that connects the computer 500 to the networks 20 and 22 illustrated in FIG. 1. The HDD 508 is a non-volatile storage device that stores programs or data.

The external I/F 503 is an interface to an external device. The computer 500 may perform reading on a recording medium 503a, such as a secure digital (SD) memory card, via the external I/F 503. The external I/F 503 may perform recording on the recording medium 503a, such as an SD memory card, via the external I/F 503.

The ROM 505 is a non-volatile semiconductor memory (storage device) where programs and data are stored. The RAM 504 is a volatile semiconductor memory (storage device) that temporarily holds programs and data. The CPU 506 is a computing device that reads programs and data from the storage device such as the ROM 505 or the HDD 508 and executes a processing to implement control and functions of the entire computer 500.

The apparatus controller 12, the autonomous controller 14, the server device 16, and the operator terminal 18 of the semiconductor manufacturing system 1 illustrated in FIG. 1 implement various functions by executing a program with the computer 500.

### <Functional Configuration>

Hereinafter, an example in which an information processing apparatus that further improves reliability of data for detecting an abnormality in the semiconductor manufacturing apparatus 10 is the autonomous controller 14 will be described. The information processing apparatus that further improves the reliability of data for detecting an abnormality in the semiconductor manufacturing apparatus 10 may also be the apparatus controller 12, the server device 16, or the operator terminal 18.

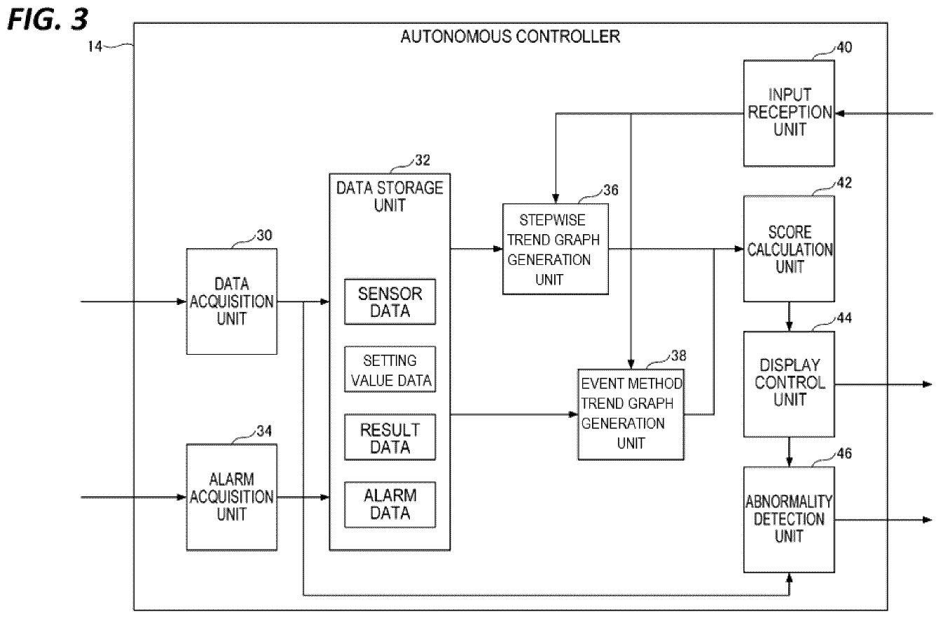

The autonomous controller 14 of the semiconductor manufacturing system 1 according to the present embodiment is implemented by, for example, functional blocks illustrated in FIG. 3. FIG. 3 is a functional block diagram of the autonomous controller 14 according to the present embodiment. The functional block diagram of FIG. 3 does not illustrate configurations unnecessary for the explanation of the present embodiment.

The autonomous controller 14 executes a program for the autonomous controller 14 to implement a data acquisition unit 30, a data storage unit 32, an alarm acquisition unit 34, a stepwise trend graph generation unit 36, an event method trend graph generation unit 38, an input reception unit 40, a score calculation unit 42, a display control unit 44, and an abnormality detection unit 46.

The data acquisition unit 30 acquires information regarding the semiconductor manufacturing apparatus 10 that executes a process according to a setting value (setting value of a process executed by the semiconductor manufacturing apparatus 10, sensor data used when the process is executed according to the setting value, and result data). The information regarding the semiconductor manufacturing apparatus 10 acquired by the data acquisition unit 30 is stored in the data storage unit 32 for each Run as a process log (history information). The information regarding the semiconductor manufacturing apparatus 10 acquired by the data acquisition unit 30 is transmitted to the abnormality detection unit 46.

The semiconductor manufacturing system 1 according to the present embodiment divides the process into a plurality of processing steps (sections), and sets a setting value for each processing step. The data storage unit 32 stores the information regarding the semiconductor manufacturing apparatus 10 for each processing step.

The alarm acquisition unit 34 acquires alarm data that is issued when a specific event occurs in the semiconductor manufacturing apparatus 10, and stores the alarm data in the data storage unit 32. The alarm data includes information (e.g., the time of alarm occurrence) that is used by an operator to designate an alarm as an analysis target, for example.

The input reception unit 40 receives various designations from the operator. For example, the designations received from the operator include the designation of an alarm as an analysis target. The stepwise trend graph generation unit 36 generates trend graphs in a stepwise manner (to be described below), based on an alarm designated by the operator as an analysis target. The event method trend graph generation unit 38 generates trend graphs according to an event method described below, based on an alarm designated by the operator as an analysis target.

The score calculation unit 42 calculates the scores of the generated trend graphs, based on one or more scoring methods described below. The display control unit 44 displays the generated trend graphs in ranking using the scores calculated by the score calculation unit 42.

The abnormality detection unit 46 may set a management value for detecting an abnormality in the semiconductor manufacturing apparatus 10, based on a trend graph selected by the operator as a reference for the score from the generated trend graphs. The abnormality detection unit 46 may automatically select a trend graph with the highest score and set a management value for detecting an abnormality in the semiconductor manufacturing apparatus 10, based on the automatically selected trend graph. The abnormality detection unit 46 detects the abnormality of the semiconductor manufacturing apparatus 10, based on the set management value and a statistical value of the sensor data acquired by the data acquisition unit 30.

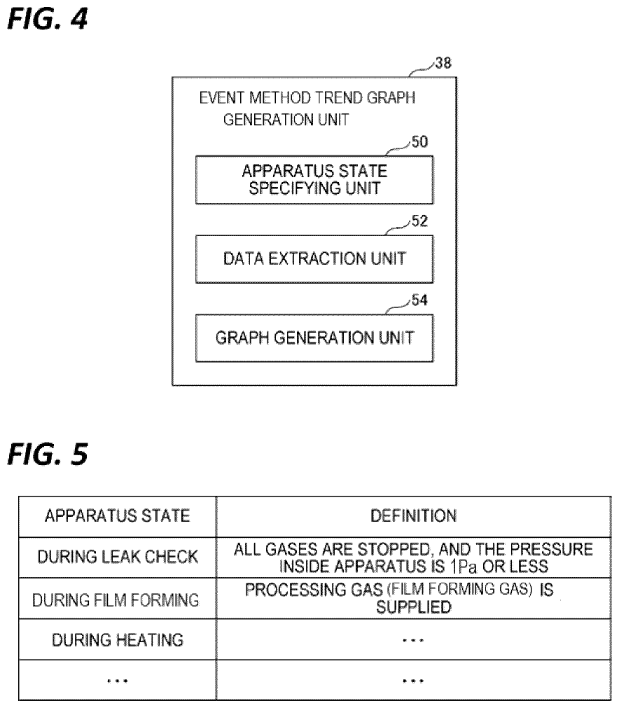

FIG. 4 is a functional block diagram of the event method trend graph generation unit 38 according to the present embodiment. The functional block diagram of FIG. 4 does not illustrate configurations unnecessary for the explanation of the present embodiment.

The event method trend graph generation unit 38 illustrated in FIG. 4 includes an apparatus state specifying unit 50, a data extraction unit 52, and a graph generation unit 54.

The apparatus state specifying unit 50 specifies the state of the semiconductor manufacturing apparatus 10 at the time when a specific event occurred, by referring to information defining the state (event) of the semiconductor manufacturing apparatus 10. FIG. 5 is an explanatory diagram of the information defining the state of the semiconductor manufacturing apparatus 10. The apparatus state specifying unit 50 specifies the state of the semiconductor manufacturing apparatus 10 at the time of alarm occurrence, using, for example, the information defining the state of the semiconductor manufacturing apparatus 10 illustrated in FIG. 5.

The data extraction unit 52 extracts, from the data storage unit 32, history information of sensor data of an event section corresponding to the state of the semiconductor manufacturing apparatus 10 at the time of alarm occurrence. The history information of the sensor data extracted by the data extraction unit 52 is also called trace data.

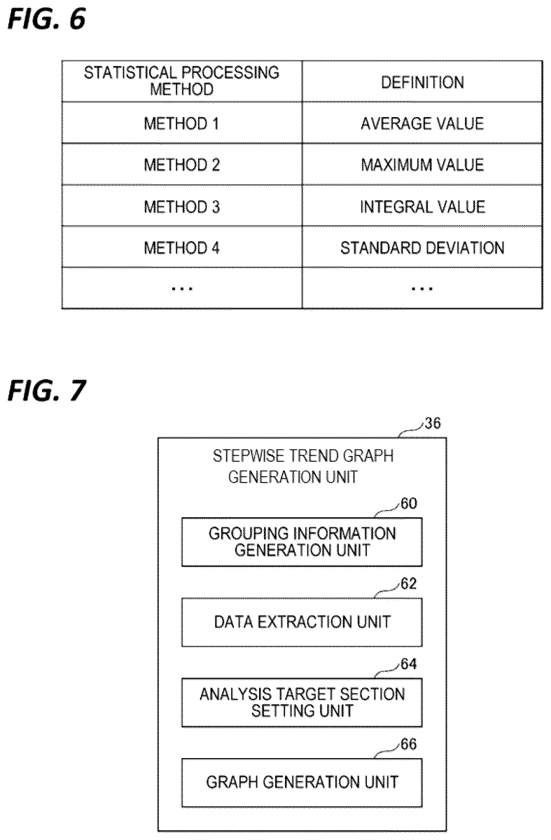

The graph generation unit 54 generates a trend graph indicating time series data that is statistically processed from the sensor data, by referring to information defining a statistical processing method. The graph generation unit 54 specifies a statistical processing method for generating the trend graph, by referring to, for example, the information defining the statistical processing method. The information defining the statistical processing method defines a method which is used for statistically processing the sensor data. FIG. 6 is an explanatory diagram of the information defining the statistical processing method.

FIG. 7 is a functional block diagram of the stepwise trend graph generation unit 36 according to the present embodiment. The functional block diagram of FIG. 7 does not illustrate configurations unnecessary for the explanation of the present embodiment.

The stepwise trend graph generation unit 36 illustrated in FIG. 7 includes a grouping information generation unit 60, a data extraction unit 62, an analysis target section setting unit 64, and a graph generation unit 66.

The grouping information generation unit 60 generates a step catalog, which is described below, from the setting value for each processing step of the process executed by the semiconductor manufacturing apparatus 10 in the past Run stored in the data storage unit 32. The step catalog is an example of information for grouping processing steps that are executed according to the same setting value.

The data extraction unit 62 specifies the setting value of the processing step (an example of a first processing step) where an alarm occurred from the time of alarm occurrence. The data extraction unit 62 searches whether a specific setting value is included in the step catalog.

When the specific setting value is included in the step catalog, the data extraction unit 62 extracts one or more processing steps (an example of a second processing step) which are processing steps having a setting value identical to the specific setting value, and which are executed before the first processing step.

The analysis target section setting unit 64 sets the first processing step and the second processing step as an analysis target section. The graph generation unit 66 generates a trend graph indicating an analysis result of the analysis target section by using the statistical value of the sensor data of the semiconductor manufacturing apparatus 10 in the analysis target section.

### <Processings>

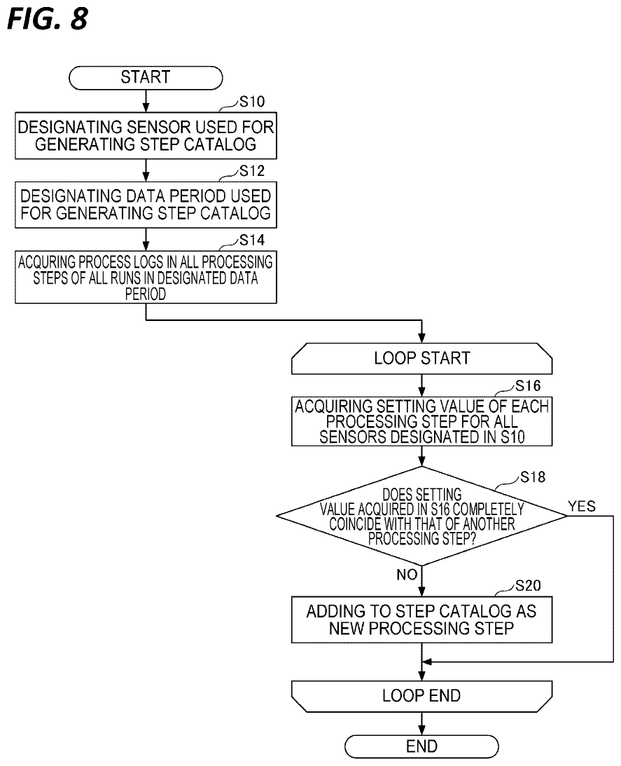

The grouping information generation unit 60 generates a step catalog by, for example, a processing procedure illustrated in FIG. 8. FIG. 8 is a flowchart of a process for generating a step catalog according to the present embodiment.

In step S10, the grouping information generation unit 60 receives, from the operator, the designation of the sensor of the semiconductor manufacturing apparatus 10 used for generating the step catalog.

In step S12, the grouping information generation unit 60 receives, from the operator, the designation of a data period of the semiconductor manufacturing apparatus 10 used for generating the step catalog.

In step S14, the grouping information generation unit 60 acquires process logs of all processing steps of all Runs in the data period designated to the operator in step S12 from the data storage unit 32.

The grouping information generation unit 60 performs the processings of steps S16 to S20 on the process logs of each processing step in each Run acquired in step S14.

In step S16, the grouping information generation unit 60 acquires the setting values of each processing step for all sensors designated to the operator in step S10. In step S18, the grouping information generation unit 60 determines whether the setting value of the processing step acquired in step S16 completely coincides with the setting value of the processing step (another processing step) included in the step catalog.

When the setting value of the processing step acquired in step S16 does not completely coincide with the setting value of the other processing step, the grouping information generation unit 60 proceeds to step S20. The grouping information generation unit 60 adds the setting value of the processing step acquired in step S16 to the step catalog as a new processing step. When the setting value of the processing step acquired in step S16 completely coincides with the setting value of the other processing step, the grouping information generation unit 60 skips the processing of step S20.

By the processings of the flowchart of FIG. 8, the grouping information generation unit 60 may generate a step catalog as information for grouping processing steps that are executed according to the same setting value. The step catalog is used to classify or compare the processing steps executed according to the same setting value.

In the flowchart of FIG. 8, an example of receiving the designation of the data period of the semiconductor manufacturing apparatus 10 used for generating a step catalog from an operator has been described, but the designation may be performed by batch processing at predetermined intervals.

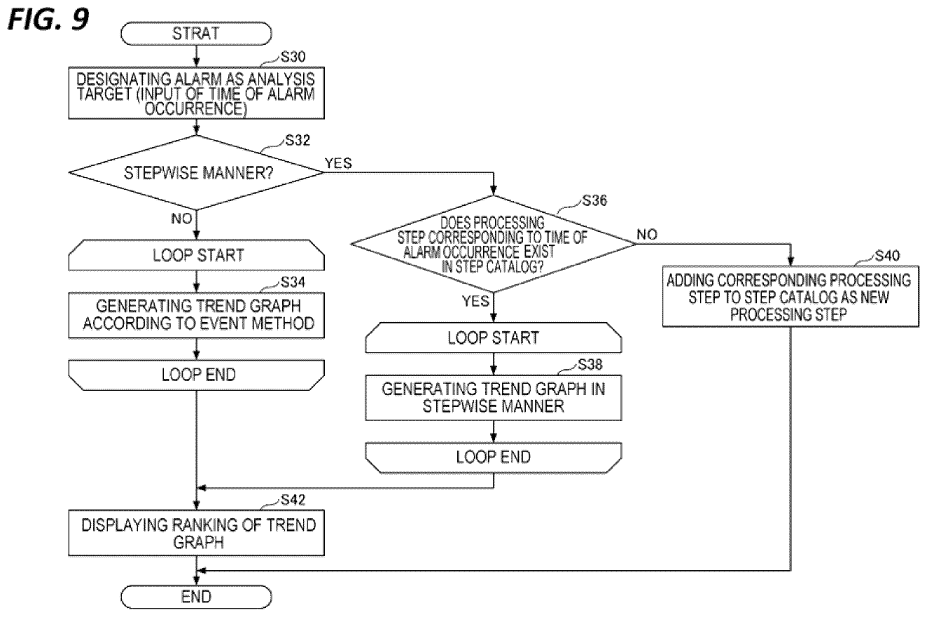

The autonomous controller 14 according to the present embodiment displays trend graphs in ranking by, for example, a processing procedure illustrated in FIG. 9. FIG. 9 is a flowchart of a process for displaying a trend graph according to the present embodiment.

In step S30, the input reception unit 40 receives the designation of an alarm as an analysis target from an operator. The designation of the alarm as the analysis target may be performed by, for example, inputting the time of alarm occurrence.

In step S32, the input reception unit 40 determines whether stepwise generation of the trend graph is selected. When the stepwise generation of the trend graph is not selected, the event method trend graph generation unit 38 generates a trend graph according to the event method in step S34.

When the stepwise generation of the trend graph is selected, the stepwise trend graph generation unit 36 proceeds to step S36. In step S36, the stepwise trend graph generation unit 36 specifies the setting value of the processing step (corresponding processing step) where an alarm occurred from the time of alarm occurrence. The stepwise trend graph generation unit 36 determines whether a specific setting value exists in the step catalog.

When the specific setting value exists in the step catalog, the stepwise trend graph generation unit 36 generates a trend graph in a stepwise manner in step S38. When the specific setting value does not exist in the step catalog, the stepwise trend graph generation unit 36 proceeds to step S40. In step S40, the stepwise trend graph generation unit 36 adds the corresponding processing step as a new processing step to the step catalog, and then ends the process of the flowchart of FIG. 9.

The process proceeds to the processing of step S42 following step S34 or S38, and the score calculation unit 42 calculates the score of the trend graph generated in step S34 or S38 based on one or more scoring methods described below. The display control unit 44 displays the generated trend graph in ranking using the score calculated by the score calculation unit 42, and then ends the processing of the flowchart of FIG. 9.

The trend graph is a graph that plots statistical values of trace data in each processing step of each Run in time series, and is, for example, an SPC chart. The operator may select a trend graph by referring to the scores from the trend graphs in which the ranking is displayed.

The generation of the trend graph according to the event method illustrated in step S34 will be described further. The apparatus state specifying unit 50 specifies a state corresponding to the state of the semiconductor manufacturing apparatus 10 at the time of alarm occurrence, by using information defining the state of the semiconductor manufacturing apparatus 10 illustrated in FIG. 5.

Next, the data extraction unit 52 extracts, from the data storage unit 32, the history information of the sensor data of the event section corresponding to the state of the semiconductor manufacturing apparatus 10 at the time of alarm occurrence (e.g., during LEAK CHECK).

Next, the graph generation unit 54 selects a method for statistically processing the history information of the sensor data of the extracted event section by referring to the information defining the statistical processing method illustrated in FIG. 6, and generates a trend graph according to the event method using the selected statistical processing method.

For example, the event method trend graph generation unit 38 extracts past sensor data near an event section where a trouble occurred, and generates a plurality of SPC charts. When an average value is selected in the statistical processing method, the event method trend graph generation unit 38 generates an SPC chart of the average value of past sensor data near the event section where the trouble occurred.

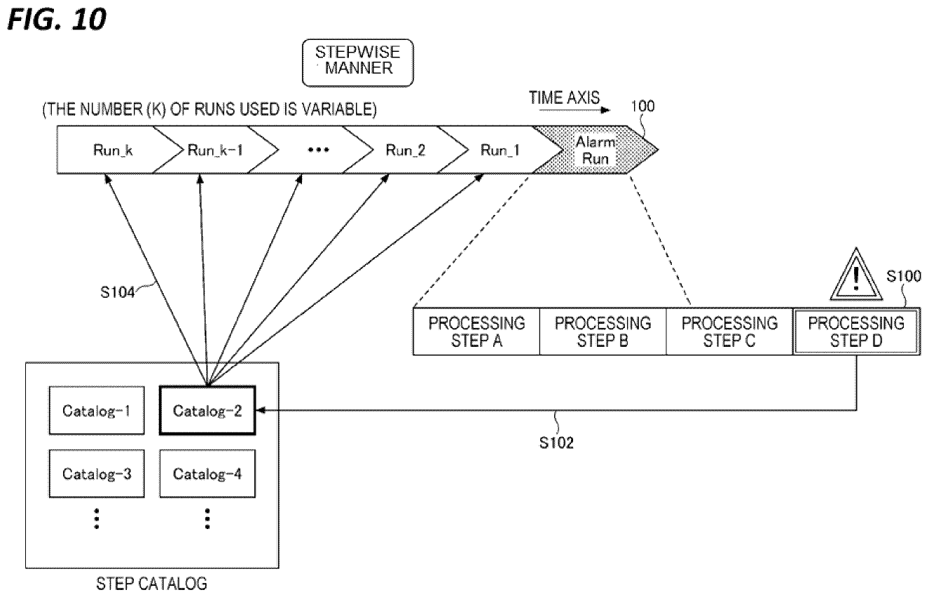

The stepwise generation of the trend graph illustrated in step S38 will be described further. FIG. 10 is a diagram illustrating the stepwise generation of the trend graph. FIG. 10 describes the Run of the semiconductor manufacturing apparatus 10 where an alarm occurred as Alarm Run 100.

In step S100, the data extraction unit 62 specifies a setting value of a processing step (processing step D) of the Alarm Run 100 where the alarm occurred from the time of alarm occurrence of the Alarm Run 100.

In step S102, the data extraction unit 62 determines whether a processing step of a specific setting value has been executed in the past by searching the step catalog using the specific setting value in step S100. FIG. 10 illustrates an example in which the setting value of “Catalog-2” included in the step catalog is identical to the specific setting value in step S100.

When it is determined that the processing step of the specific setting value has been executed in the past, the data extraction unit 62 proceeds to step S104. The data extraction unit 62 extracts the processing step of one or more Runs (Run_k to Run_1), which is the processing step having a setting value identical to that of the processing step D specified in step S100 and which was executed before Alarm Run 100.

When it is determined that the processing step of a specific setting value has not been executed in the past, the grouping information generation unit 60 adds the setting value of the processing step D acquired in step S100 to the step catalog, as a new processing step.

The analysis target section setting unit 64 sets the processing step D in which the alarm occurred and a processing step extracted in step S104 as an analysis target section. The data extraction unit 62 extracts the history information of the sensor data of the analysis target section from the data storage unit 32.

Next, the graph generation unit 66 selects a method for statistically processing the extracted history information of the sensor data of the analysis target section by referring to the information defining the statistical processing method illustrated in FIG. 6, and generates a trend graph in a stepwise manner, using the selected statistical processing method.

For example, the stepwise trend graph generation unit 36 extracts the sensor data of the processing step of the analysis target section and generates a plurality of SPC charts. When an average value is selected in the statistical processing method, the stepwise trend graph generation unit 36 generates an SPC chart of the average value of the sensor data in the processing step of the analysis target section.

The ranking display of the trend graph illustrated in step S42 will be described further. The score calculation unit 42 calculates the score of the generated trend graph based on one or more scoring methods.

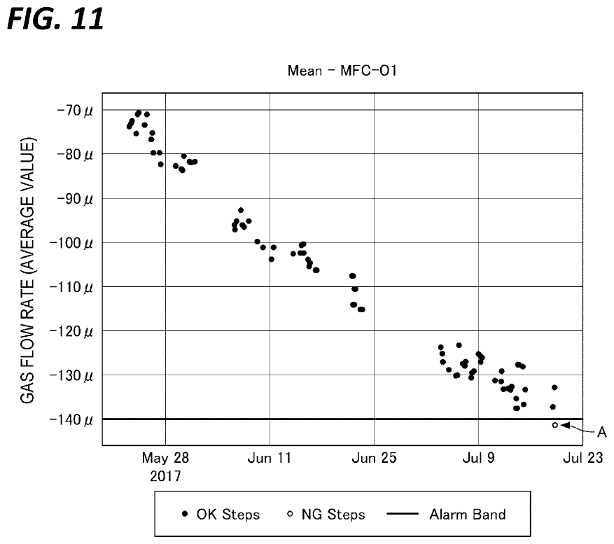

FIG. 11 is a diagram illustrating an example of a generated trend graph. The horizontal axis of the trend graph illustrated in FIG. 11 represents the time, and the vertical axis represents an average value of gas flow rates. The average value of the gas flow rates is an example of a statistical value. The statistical value may be, for example, a standard deviation of the gas flow rates or a value obtained by statistically processing other sensor data.

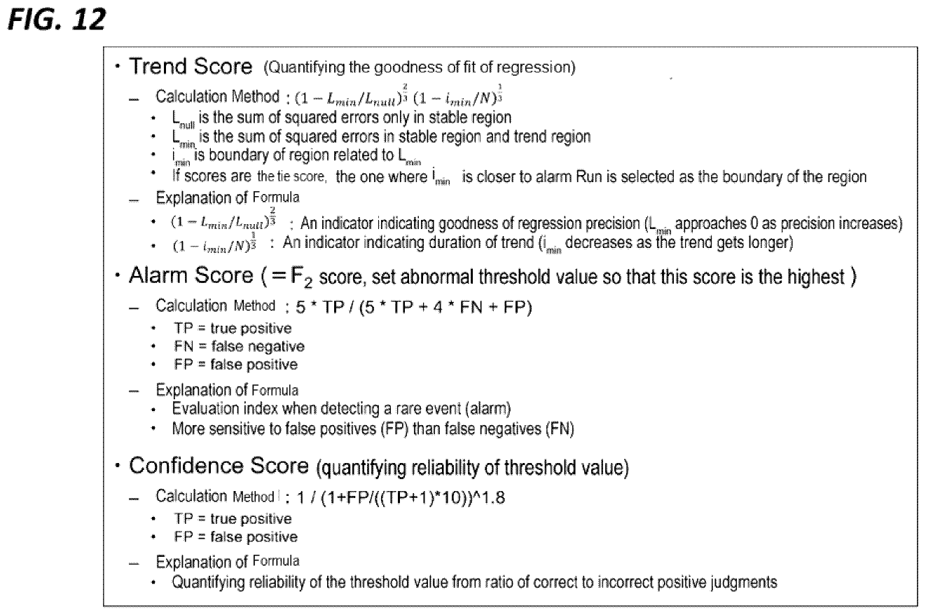

FIG. 12 is a diagram illustrating a scoring method for calculating the score of the trend graph. The scoring method for calculating the score of the trend graph uses, for example, a scoring method for calculating a trend score, an alarm score, or a confidence score illustrated in FIG. 12. The scoring method for calculating the score of the trend graph is not limited to the scoring method of FIG. 12, and may use other scoring methods, such as a scoring method using a regression coefficient, for example.

The operator selects one trend graph by referring to the scores from the trend graphs in which ranking is displayed, for example. The abnormality detection unit 46 may set a management value for detecting an abnormality in the semiconductor manufacturing apparatus 10, based on the trend graph selected by the operator by referring to the scores from the generated trend graphs. The management value is at least one of an upper limit value and a lower limit value of the trend graph used to issue an alarm.

For example, in the trend graph of FIG. 11, a management value (a line indicated by Alarm Band in FIG. 11) for issuing an alarm is set. The abnormality detection unit 46 may monitor statistical values of the sensor data of the semiconductor manufacturing apparatus 10 using the management value set as illustrated in FIG. 11, for example, and detect an abnormality in the semiconductor manufacturing apparatus 10.

With the semiconductor manufacturing system 1 according to the present embodiment, a measurement section when generating a trend graph according to the event method may be set using the event section defined in advance for each semiconductor manufacturing apparatus 10.

In addition, with the semiconductor manufacturing system 1 according to the present embodiment, by grouping processing steps of the same setting value, it is possible to set an analysis target section when generating a trend graph in a stepwise manner. Furthermore, with the semiconductor manufacturing system 1 according to the present embodiment, by grouping processing steps of the same setting value, there is no need to compare statistical values of processing steps of different setting values, and thus, the reliability of the trend graph generated in a stepwise manner is improved.

In addition, with the semiconductor manufacturing system 1 according to the present embodiment, when generating a trend graph in a stepwise manner, since an unknown processing step is automatically added to the step catalog as a new processing step, the step catalog grows itself and the unknown processing step may be handled as a known processing step from the next time. Furthermore, with the semiconductor manufacturing system 1 according to the present embodiment, when generating a trend graph in a stepwise manner, a processing step other than the time of alarm occurrence may be set as an analysis target section.

The semiconductor manufacturing system 1 according to the present embodiment may be used by generating a step catalog 10 for each semiconductor manufacturing apparatus 10, or may be used by generating the step catalog 10 for a plurality of semiconductor manufacturing apparatuses 10.

The semiconductor manufacturing apparatus 10 of the present disclosure may be applied to any type of apparatuses, such as an atomic layer deposition (ALD) apparatus, a capacitively-coupled plasma (CCP) apparatus, an inductively-coupled plasma (ICP) apparatus, a radial line slot antenna (RLSA) apparatus, an electron cyclotron resonance plasma (ECR) apparatus, or a helicon wave plasma (HWP) apparatus. The semiconductor manufacturing apparatus 10 of the present disclosure may also be applied to a chemical vapor deposition (CVD) apparatus and an oxidation/annealing apparatus.

The semiconductor manufacturing system 1 of the present disclosure is not limited to the configuration illustrated in FIG. 1, and there may be various examples of system configurations depending on usage or purposes. The semiconductor manufacturing apparatus 10 of the present disclosure may be applied to any of a single-substrate processing apparatus that processes substrates one by one, a batch apparatus that processes a plurality of substrates at once, and a semi-batch apparatus. The process performed by the semiconductor manufacturing apparatus 10 of the present disclosure may include, for example, a film forming process, an etching process.

According to the present disclosure, it is possible to further improve the reliability of data for detecting an abnormality in a semiconductor manufacturing apparatus.

From the foregoing, it will be appreciated that various embodiments of the present disclosure have been described herein for purposes of illustration, and that various modifications may be made without departing from the scope and spirit of the present disclosure. Accordingly, the various embodiments disclosed herein are not intended to be limiting, with the true scope and spirit being indicated by the following claims.

What is claimed is:

1. An information processing apparatus comprising:
grouping information generation circuitry configured to acquire a setting value for each processing step executed by a semiconductor manufacturing apparatus according to the setting value, and generate information for grouping processing steps executed according to the same setting value;
data extraction circuitry configured to extract at least one second processing step that has a setting value identical to a setting value of a first processing step and that is executed before the first processing step when the setting value of the first processing step specified from a time when an abnormality occurred is included in the information for grouping;
analysis target section setting circuitry configured to set the first processing step and the second processing step as an analysis target section; and
display control circuitry configured to display a graph indicating an analysis result of the analysis target section.

2. The information processing apparatus according to claim 1, wherein the grouping information generation circuitry add the setting value of the first processing step to the information for grouping when the setting value of the first processing step is not included in the information for grouping.

3. The information processing apparatus according to claim 1, further comprising:
graph generation circuitry configured to generate a graph illustrating an analysis result of the analysis target section using a statistical value of sensor data of the semiconductor manufacturing apparatus in the analysis target section.

4. The information processing apparatus according to claim 3, further comprising:
score calculation circuitry configured to calculate a score of the graph based on one or more scoring methods,
wherein the graph generation circuitry generate one or more graphs indicating an analysis result of the analysis target section using the statistical value calculated based on one or more statistical processing methods, and
the display control circuitry display a ranking result of the one or more graphs using the score.

5. The information processing apparatus according to claim 1, further comprising:
abnormality detection circuitry configured to detect an abnormality in the semiconductor manufacturing apparatus using a management value set based on the graph.

6. A semiconductor manufacturing apparatus comprising:
grouping information generation circuitry configured to acquire a setting value for each processing step executed, and generate information for grouping processing steps executed according to the same setting value;
data extraction circuitry configured to extract at least one second processing step that has a setting value identical to a setting value of a first processing step and that is executed before the first processing step when the setting value of the first processing step specified from a time when an abnormality occurred is included in the information for grouping;
analysis target section setting circuitry configured to set the first processing step and the second processing step as an analysis target section; and
display control circuitry configured to display a graph indicating an analysis result of the analysis target section.

7. An information processing method comprising:
acquiring a setting value for each processing step executed by a semiconductor manufacturing apparatus according to the setting value, and generating information for grouping processing steps executed according to the same setting value;
extracting at least one second processing step that has a setting value identical to a setting value of a first processing step and that is executed before the first processing step when the setting value of the first processing step specified from a time when an abnormality occurred is included in the information for grouping;
setting the first processing step and the second processing step as an analysis target section; and
displaying a graph indicating an analysis result of the analysis target section.
